(19) United States
(12) Patent Application Publication
(10) Pub. No.: US 2026/0056229 A1
(43) Pub. Date: Feb. 26, 2026

(54) COMPLIANT TEST PROBE

(71) Applicant: ADEIA SEMICONDUCTOR BONDING TECHNOLOGIES INC., San Jose, CA (US)

(72) Inventors: Cyprian Emeka Uzoh, San Jose, CA (US); Oliver Zhao, Sunnyvale, CA (US); Arianna M. Avellán Jaramillo, Fremont, CA (US); Suhail J. Sadiq, Dublin, CA (US)

(21) Appl. No.: 18/924,596

(22) Filed: Oct. 23, 2024

Related U.S. Application Data
(60) Provisional application No. 63/687,233, filed on Aug. 26, 2024.

(51) Int. Cl. G01R 1/067; G01R 1/073; G01R 31/28

(52) U.S. Cl. CPC G01R 1/06716; G01R 1/06738; G01R 1/06761; G01R 1/07342; G01R 31/2886

(57) ABSTRACT

A deformable electrical testing probe is disclosed. The testing probe can include a base test structure having an electrically conductive layer comprising one or more metallic conductors. The testing probe can further include a conductive probe having an electrically conductive polymer on the one or more metallic conductors of the electrically conductive layer. The conductive probes can include a tip opposite from the electrically conductive layer, and the tip can include a conductive tip layer having a hardness greater than that of the conductive probes. One or more conductive filaments can be embedded within the conductive probes. The conductive probes can include a reinforcing material embedded within the conductive probes. The reinforcing material within the conductive probe can be a composite material and/or a metallic element. The conductive probe can be elastically deformable. The deformable electrical testing probe can minimize or eliminate probe marks on a tested device.

### RELATED APPLICATIONS

This application claims the priority benefit of U.S. Provisional Patent Application 63/687,233 filed on Aug. 26, 2024, entitled “COMPLIANT TEST PROBE,” which is incorporated by reference herein in its entirety.

### BACKGROUND

### Field

This disclosure relates to semiconductor device structures and methods. In particular, some implementations are directed to methods and structures for testing semiconductor elements via compliant test probes for testing electrical functionality of contact pads on semiconductor elements.

### Description of the Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Semiconductor devices have increased in complexity along with the need to reduce the possibility of damaging the testing surface of the semiconductor device during testing. However, it can be challenging to provide testing that adequately tests the features of a semiconductor device without damaging the bonding features of the semiconductor device. Accordingly, there remains a continuing demand for improved probing devices and processes.

### SUMMARY

For purposes of summarizing the disclosure and the advantages achieved over the prior art, certain objects and advantages of the disclosure are described herein. Not all such objects or advantages may be achieved in any particular implementation. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these implementations are intended to be within the scope of the invention herein disclosed. These and other implementations will become readily apparent to those skilled in the art from the following detailed description of the preferred implementations having reference to the attached figures, the invention not being limited to any particular preferred implementations disclosed.

In some implementations a deformable electrical testing probe can include: a base test structure having an electrically conductive layer including one or more metallic conductors; and a conductive probe including an electrically conductive polymer on the one or more metallic conductors of the electrically conductive layer.

In some implementations, the conductive probe is formed through additive manufacturing. In some implementations, the conductive probe is formed using a molding process. In some implementations, the conductive probe is formed using vacuum forming.

In some implementations, the conductive probes includes a tip opposite from the electrically conductive layer. In some implementations, the tip includes a conductive tip layer having a hardness greater than that of the conductive probes. In some implementations, the tip includes a spherical tip. In some implementations, the tip includes a triangular tip.

In some implementations, the testing probe includes one or more conductive filaments embedded within the conductive probes. In some implementations, a first set of the one or more conductive filaments includes a length less than 30% of the conductive probes and a second set of the one or more conductive filaments includes a length less than 20% of the conductive probes.

In some implementations, the testing probe includes a reinforcing material embedded within the conductive probes. In some implementations, the reinforcing material within the conductive probe includes a composite material. In some implementations, the reinforcing material within the conductive probe includes a metallic element. In some implementations, the testing probe includes an underfill around a base of the conductive probes.

In some implementations, an elastic modulus of the electrically conductive polymer is between 1 GPa to 20 GPa. In some implementations, the conductive probe is elastically deformable. In some implementations, the deformable electrical testing probe is configured to minimize or eliminate probe marks on a tested device. In some implementations, the conductive probe includes a plurality of conductive probes. In some implementations, the conductive probe is integrated with the one or more metallic conductors of the electrically conductive layer.

In some implementations, the deformable probe can include an inductive element or circuit. The inductive element is in close proximity to a test pad or trace and can sense the magnitude of current flow along a trace or between two test pads. With a suitable calibration, the deformable probe having an inductive element can be applied to test a device without scratching the test pads of the device.

In some implementations, a deformable electrical testing probe can include: a base test structure having an electrically conductive layer including one or more metallic conductors; one or more dielectric layers formed over the electrically conductive layer; and a conductive probe including an electrically conductive polymer on the one or more metallic conductors of the electrically conductive layer and protruding through the one or more dielectric layers.

In some implementations, the conductive probes are formed through additive manufacturing. In some implementations, the conductive probes are formed using a molding process. In some implementations, the conductive probes are formed using vacuum forming.

In some implementations, the conductive probes includes a tip opposite from the electrically conductive layer. In some implementations, the tip includes a conductive tip layer having a hardness greater than that of the conductive probes. In some implementations, the tip includes a spherical tip. In some implementations, the tip includes a triangular tip.

In some implementations, the testing probe includes one or more conductive filaments embedded within the conductive probe. In some implementations, a first set of the one or more conductive filaments includes a length less than 30% of the conductive probes and a second set of the one or more conductive filaments includes a length less than 20% of the conductive probes.

In some implementations, the testing probe includes a reinforcing material embedded within the conductive probes. In some implementations, the reinforcing material within the conductive probe includes a composite material. In some implementations, the reinforcing material within the conductive probe includes a metallic element.

In some implementations, an elastic modulus of the conducting polymer is between 1 GPa to 20 GPa. In some implementations, the conductive probe is elastically deformable. In some implementations, the deformable electrical testing probe minimizes or eliminates probe marks on a tested device. In some implementations, the conductive probe includes a plurality of conductive probes.

In some implementations, the one or more dielectric layers include an organic dielectric layer formed on the electrically conductive layer and an inorganic dielectric layer formed over the organic dielectric layer. In some implementations, the organic dielectric layer is thicker than the inorganic dielectric layer. In some implementations, the conductive probe is integrated with the one or more metallic conductors of the electrically conductive layer.

In some implementations, the deformable probe can include an inductive element or circuit. The inductive element is in close proximity to a test pad or trace and can sense the magnitude of current flow along a trace or between two test pads. With a suitable calibration, the deformable probe having an inductive element can be applied to test a device without scratching the test pads of the device.

In some implementations, a deformable electrical testing probe having conductive filaments can include: a base test structure including an electrically conductive layer having one or more metallic conductors; an adhesion layer formed on the electrically conductive layer and a seed layer formed on the adhesion layer; and a conductive probe including an electrically conductive polymer on the seed layer over the one or more metallic conductors of the electrically conductive layer.

In some implementations, the conductive probes are formed through additive manufacturing. In some implementations, the conductive probes are formed using a molding process. In some implementations, the conductive probes are formed using vacuum forming.

In some implementations, the conductive probes includes a tip opposite from the electrically conductive layer. In some implementations, the tip includes a conductive tip layer having a hardness greater than that of the conductive probes. In some implementations, the tip includes a spherical tip. In some implementations, the tip includes a triangular tip.

In some implementations, the testing probe includes one or more conductive filaments embedded within the conductive probes. In some implementations, the one or more conductive filaments includes a first set of conductive filaments and a second set of conductive filaments, and wherein the first set of the one or more conductive filaments includes a length less than 30% of the conductive probes and the second set of the one or more conductive filaments includes a length less than 20% of the conductive probes. In some implementations, the testing probe includes an underfill around a base of the conductive probes.

In some implementations, an elastic modulus of the electrically conductive polymer is between 1 GPa to 20 GPa. In some implementations, the conductive probe is elastically deformable. In some implementations, the conductive probe includes a plurality of conductive probes. In some implementations, the conductive probe is integrated with the seed layer over the one or more metallic conductors.

In some implementations, the deformable probe can include an inductive element or circuit. The inductive element is in close proximity to a test pad or trace and can sense the magnitude of current flow along a trace or between two test pads. With a suitable calibration, the deformable probe having an inductive element can be applied to test a device without scratching the test pads of the device.

In some implementations, a method for forming elastically deformable probes can include: providing a base test structure having an electrically conductive layer; and forming a conductive probe including an electrically conductive polymer on the electrically conductive layer.

In some implementations, forming the conductive probe includes performing an additive manufacturing process. In some implementations, forming the conductive probe includes performing a molding process. In some implementations, forming the conductive probe includes performing a vacuum forming process.

In some implementations, the method includes depositing a protective coating on a tip of the conductive probe, wherein the tip is opposite of a base of the conductive probe, the base disposed along the electrically conductive layer. In some implementations, the method includes forming one or more conductive filaments within the conductive probe. In some implementations, the method includes embedding a reinforcing material within the conductive probe.

In some implementations, embedding a reinforcing material includes embedding a composite material within the conductive probe. In some implementations, embedding a reinforcing material includes embedding a metallic element within the conductive probe. In some implementations, the method includes forming an underfill around a base of the conductive probe.

In some implementations, the conductive probe is elastically deformable. In some implementations, the elastically deformable probes minimize or eliminate probe marks on a tested device. In some implementations, the conductive probe includes forming a plurality of conductive probes.

In some implementations, a method for forming elastically deformable probes can include: providing a base test structure having an electrically conductive layer; forming one or more dielectric layers over the electrically conductive layer; patterning the one or more dielectric layers to expose the electrically conductive layer; and forming a conductive probe including an electrically conductive polymer on the exposed electrically conductive layer.

In some implementations, the method includes providing a protective layer over the one or more dielectric layers and the conductive probe. In some implementations, the method includes: planarizing a surface including the protective layer and the conductive probe to expose a portion of the conductive probe through the protective layer; and removing the protective layer from the planarized surface such that the conductive probe are protruding above the one or more dielectric layers.

In some implementations, forming the one or more dielectric layers includes forming an organic dielectric layer over the electrically conductive layer and an inorganic dielectric layer over the organic dielectric layer, and further including patterning the organic dielectric layer and the inorganic dielectric layer to expose the electrically conductive layer. In some implementations, the organic dielectric layer is thicker than the inorganic dielectric layer.

In some implementations, forming the conductive probe includes performing an additive manufacturing process. In some implementations, forming the conductive probe includes performing a molding process. In some implementations, forming the conductive probe includes performing a vacuum forming process.

In some implementations, the method includes depositing a protective coating on a tip of the conductive probe. In some implementations, the method includes forming one or more conductive filaments within the conductive probe. In some implementations, the method includes embedding a reinforcing material within the conductive probe. In some implementations, embedding a reinforcing material includes embedding a composite material within the conductive probe. In some implementations, embedding a reinforcing material includes embedding a metallic element within the conductive probe.

In some implementations, the conductive probe is elastically deformable. In some implementations, the elastically deformable probes minimize or eliminate probe marks on a tested device. In some implementations, forming the conductive probe includes forming a plurality of conductive probes.

In some implementations, a method for forming elastically deformable probes having conductive filaments, the method including: providing a base test structure having an electrically conductive layer; forming an adhesion layer along the base test structure and forming a seed layer on the adhesion layer; coating a resist layer over the seed layer; patterning the resist layer to form cavities extending from the seed layer to a top surface of the resist layer opposite the seed layer; forming a conductive layer within the patterned cavities to create the conductive filaments; removing the resist layer, the seed layer, and the adhesion layer from the base test structure to expose the conductive filaments; and forming a conductive probe including an electrically conductive polymer on the conductive filaments.

In some implementations, the method includes planarizing the top surface of the resist layer. In some implementations, forming the conductive probe includes performing an additive manufacturing process. In some implementations, forming the conductive probe includes performing a molding process. In some implementations, forming the conductive probe includes performing a vacuum forming process.

In some implementations, the method includes depositing a protective coating on a tip of the conductive probe, wherein the tip includes a surface of the conductive probe opposite the electrically conductive layer. In some implementations, the method includes forming an underfill around a base of the conductive probe. In some implementations, the conductive probe is elastically deformable.

In some implementations, a method of testing a tested device with elastically deformable probes can include: providing a base test structure having a conductive probe; contacting a plurality of test pads of the device with the conductive probe; testing the plurality of test pads of the tested device; and disconnecting the conductive probe from the plurality of test pads.

In some implementations, no indentation of a mark or a defect is left on a surface of the plurality of test pads of the tested device during contacting of the plurality of test pads. In some implementations, the conductive probe elastically deforming to minimize or eliminate probe marks on the tested device. In some implementations, contacting the plurality of tests pads leaves an indentation on a surface of the plurality of test pads of a depth tests pads of a depth less than 300 nm. In some implementations, contacting the plurality of tests pads leaves an indentation on a surface of the plurality of test pads of a depth less than 100 nm.

In some implementations, a protective spherical tip prevents indentation defects during contacting of the plurality of test pads. In some implementations, the method includes applying a force to the conductive probe such that it deforms and conforms to a surface geometry of the plurality of test pads without leaving permanent indentations.

In some implementations, applying the force to the conductive probe ensures complete contact without damaging surface geometry of the plurality of test pads. In some implementations, the method includes establishing an electrical contact between the conductive probe and the plurality of test pads. In some implementations, the method includes: measuring electrical properties of the plurality of test pads through the conductive probe; and analyzing the measured electrical properties to determine a quality of the tested device.

### BRIEF DESCRIPTION OF THE DRAWINGS

These and other features, aspects, and advantages of the disclosure are described with reference to drawings of certain implementations, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1 illustrates a side sectional view of a conventional process for testing a test pad of a semiconductor element.

FIG. 2A illustrates schematic side sectional view of an elastically deformable testing probe and a semiconductor element, according to various implementations.

FIG. 2B and FIG. 2C illustrate schematic side sectional views of the elastically deformable testing probe of FIG. 2A having various tip configurations.

FIG. 3 illustrates a schematic side sectional view of another exemplary elastically deformable testing probe and the semiconductor element, according to various implementations.

FIG. 4 illustrates a schematic side sectional view of another exemplary elastically deformable testing probe and the semiconductor element, according to various implementations.

FIG. 5 is a graphical flow diagram illustrating an example process for fabricating the testing probe of FIG. 4 reinforced with conductive particles.

FIG. 6 is another graphical flow diagram illustrating another example process for fabricating the testing probe of FIG. 4 reinforced with conductive particles.

FIG. 7 is a graphical flow diagram illustrating an example process for fabricating the testing probe of FIG. 3 having one or more conductive filaments embedded within the conductive probe.

FIG. 8A is a schematic cross-sectional side view of two elements prior to direct hybrid bonding.

FIG. 8B is a schematic cross-sectional side view of a bonded structure including the two elements shown in FIG. 8A after direct hybrid bonding.

### DETAILED DESCRIPTION

Although several implementations, examples, and illustrations are disclosed below, it will be understood by those of ordinary skill in the art that the inventions described herein extend beyond the specifically disclosed implementations, examples, and illustrations and includes other uses of the inventions and obvious modifications and equivalents thereof. Implementations are described with reference to the accompanying figures, wherein like numerals refer to like elements throughout. The terminology used in the description presented herein is not intended to be interpreted in any limited or restrictive manner simply because it is being used in conjunction with a detailed description of some specific implementations of the inventions. In addition, implementations can comprise several novel features. No single feature is solely responsible for its desirable attributes or is essential to practicing the inventions herein described.

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of implementations.

There is significant demand for reducing and/or eliminating the damage to semiconductor elements when probe testing. Conventional probing methods involve the use of specialized equipment known as probe stations or probe testers. These systems facilitate electrical contact with the semiconductor element's internal circuits via probe needles and/or pins. The probing process includes several stages, such as initial contact, signal transmission, data acquisition, and result analysis. Each stage is designed to validate different aspects of the semiconductor element's performance and integrity. Probing equipment can include a probe station comprising a mechanical apparatus that holds the semiconductor element securely in place during testing. The probe stations further include a microscope and/or cameras for precise alignment and positioning of probe needles. Additionally, the probing equipment can further include a probe card which is an interface containing multiple probe needles or pins that make physical contact with the contact pads of the semiconductor element. The probe card is designed to match the layout of the contact pads of the semiconductor element. Lastly, the probing equipment can include a signal generator and/or analyzer which are devices used to generate test signals and analyze the response of the semiconductor element. The signal generator and/or analyzer are connected to the probe card through electrical wires and/or cables.

During the probing process, the semiconductor elements are placed on the probe station's platform and aligned with assistance of a microscope and/or cameras. This ensures that the probe needles accurately contact the pads of the semiconductor elements. Next, the probe card is positioned above the semiconductor elements. Using fine adjustment controls, the probe needles are lowered until they make contact with the pads of the semiconductor elements. The force applied is monitored to prevent damage to the semiconductor element, however, the probe needles can scratch the pads. Consequently, the semiconductor elements require additional processing and/or reconditioning before they can be prepared for hybrid bonding. Test signals are transmitted into the semiconductor elements through the probe needles. These signals are designed to activate various circuits within the semiconductor elements, simulating operational conditions. The semiconductor element's responses to the test signals are captured and recorded by circuitry included in the probe card. This data includes voltage levels, current flows, and timing information, which are important for assessing the performance of the semiconductor elements. The acquired data is then analyzed to determine the functionality and performance of the semiconductor elements. This analysis identifies defects such as open circuits, short circuits, and/or parameter deviations from specifications.

Probing techniques can also include measuring specific electrical parameters, such as threshold voltage and/or leakage current, to ensure they fall within acceptable ranges. Additionally, functional testing of the semiconductor element assesses the ability of the semiconductor element to perform its intended functions under various conditions. Functional tests often include checking logic operations, memory read/write cycles, and/or communication protocols. In a burn-in testing, the semiconductor element is subjected to elevated temperatures and voltages to accelerate aging and reveal potential reliability issues. Probes monitor the behavior of the semiconductor element throughout the burn-in period. Lastly, dynamic testing can utilize real-time signals transmitted into the semiconductor element to mimic actual operating conditions. This tests the performance of the semiconductor element under dynamic loads and high-frequency operation.

As mentioned above, one of the challenges in the probing process is the potential for damage to the semiconductor element caused by the probe needles. Probe needles are designed to make contact with the probe pads of the semiconductor element to facilitate electrical testing. In some testing procedures, the probe needle has to scrape through a preliminary layer, such as an oxide layer, formed (e.g., naturally formed) on the contact pad (e.g., aluminum oxide on aluminum (Al) pads) in order to access the metal of the contact pad. The probing process can cause physical damage to the contact pads, leading to scratches, burrs, and/or gouges on the semiconductor element, and/or short circuits caused by debris from damaged contact pads (commonly known as probe marks). Such probe marks can be tolerated by wire bonding. For flip chip soldering, the probe marks are covered over by a metal layer commonly known as under-bump metallurgy (UBM). The UBM layer is deposited after the wafer probing process. The UBM layer fabrication is time-consuming and add costs. For hybrid bonding, such damage can be repaired by methods described in U.S. Pat. No. 11,355,404, which is incorporated by reference herein, which can be time consuming and require additional steps. Once the repair is completed, additional oxide layers are deposited, which are then planarized, and conductive material (e.g., copper) is added. Thus, there is a continued need for improving the testing instrumentations for semiconductor elements without damaging said semiconductor elements and/or contact pads of said semiconductor elements.

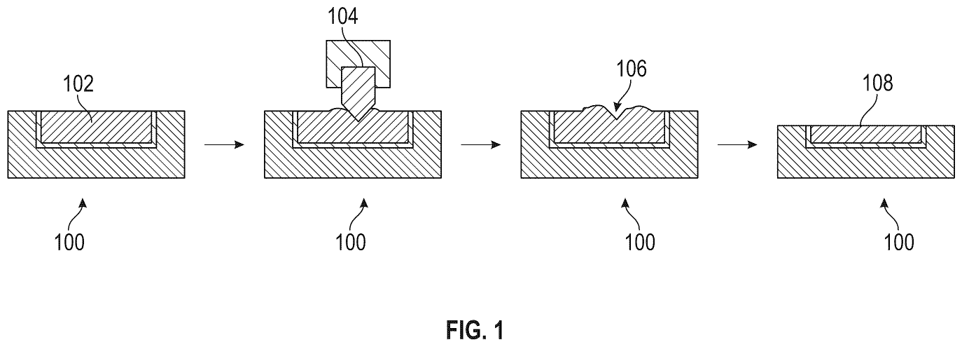

FIG. 1 illustrates a side sectional view of a conventional process for testing a test pad 102 of a semiconductor element 100. During conventional testing methods, testing probes (e.g., testing probe 104) contact the test pad 102 (e.g., probe pads), which can introduce scratch marks onto the test pad 102. The testing probe 104 can also deform the test pad 102 in such a manner that a portion of the tested pad may protrude over the bonding surface of the test pad 102. The scratch marks and protrusions on the test pad 102 can hinder the hybrid bonding process. For example, conventional testing methods can result in damage 106 (e.g., indentations, burrs) that can be approximately 2 μm high on the test pad 102 and unwanted particles on the semiconductor element 100. Said damage can require substantial work to repair and/or recondition the test pad 102 for a hybrid bonding process. A surface 108 of the test pad 102 can be planarized (e.g., brush cleaning, CMP methods) to remove undesirable defects on the semiconductor element 100. The additional planarization process can add undesirable cost to device fabrication.

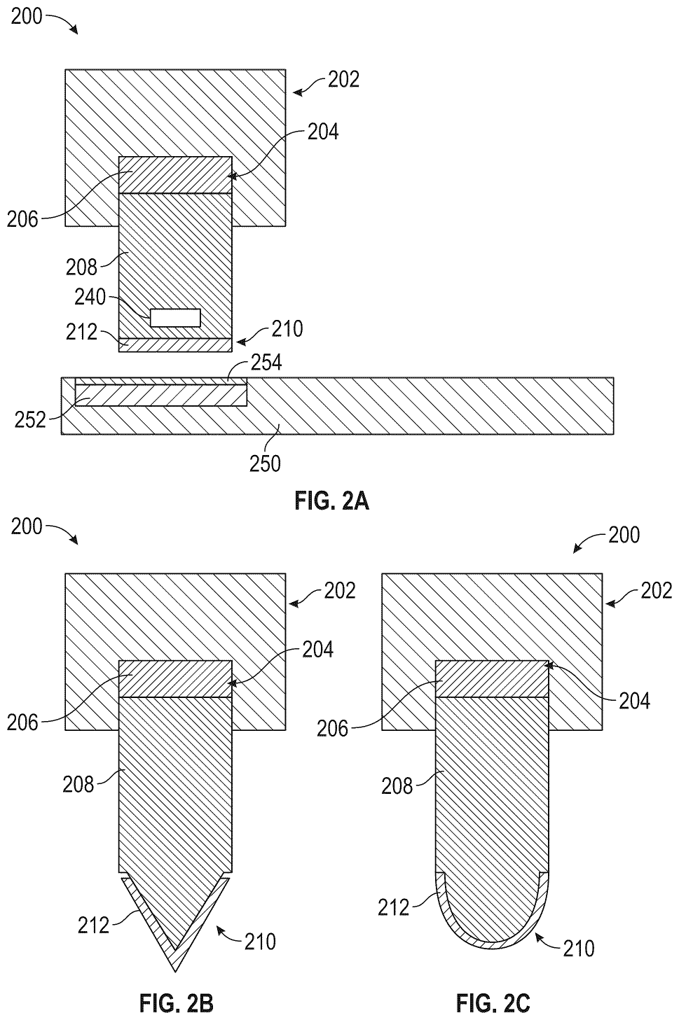

FIG. 2A illustrates schematic side sectional view of an elastically deformable testing probe 200 and a semiconductor element 250. FIG. 2B and FIG. 2C illustrate schematic side sectional view of the testing probe 200 having various tip configurations. The testing probe 200 can include a base test structure 202 having an electrically conductive layer 204. The electrically conductive layer 204 can include metallic conductors 206. The metallic conductors 206 can be made of gold, silver, copper, aluminum, nickel, and/or any suitable metal. A conductive probe 208 can be formed on (e.g., integrated with, bonded, connected, attached, etc.) one or more metallic conductors 206. In some implementations, for example, the metallic conductors 206 and the conductive probe 208 can form a seamless and/or unitary body. The conductive probe 208 can be made of an electrically conductive polymer. An electrically conductive polymer can be an electrically conductive organic polymer capable of conducting electricity, combining the flexibility and lightweight nature of plastics with the electrical properties of metals and/or semiconductors. These polymers, such as polyaniline (PANI), polypyrrole (PPy), and PEDOT, achieve conductivity through conjugated double bonds and doping. Conductive polymers can be used in applications like organic light-emitting diodes (OLEDs), sensors, batteries, antistatic coatings, and/or flexible electronics due to their processability, chemical versatility, and ability to be tailored for specific properties. In some implementations, the conductive polymer of the conductive probe 208 includes polyacetylene (PA), polyaniline (PANI), polystyrene-sulphonate (PEDOT:PSS), polypyrrole (PPy), polythiophene (PT), and poly(o-phenylene-diamine) (PoPDA).

The conductive probe 208 can further include a tip 210 on an end opposite of the electrically conductive layer 204. In some implementations, the tip 210 can include a conductive and/or protective tip layer 212 for further preventing indentation defects to a test pad (e.g., test pad 252). The protective tip layer 212 can have a hardness greater than that of the conductive probe 208. The tip layer 212 can be comprised of various materials such as Indium Tin Oxide (ITO), Rhodium, Iridium, etc. ITO is an alloy comprised primarily of indium oxide (In2O3) and tin oxide (SnO2) in a ratio of 90% to 10% by weight. ITO can be deposited as a thin film using techniques like sputtering and/or thermal evaporation. ITO (e.g., ITO films) can provide environmental protection by offering resistance to moisture, chemicals, and/or temperature fluctuations to extend operational lifespan. Like ITO, Rhodium and Iridium can be used for their electrical conductivity, high durability, and/or resistance to corrosion and oxidation. The protective tip layer 212 can include various shapes such as a triangular tip (see FIG. 2B), a spherical tip (see FIG. 2C), etc. The electrically conductive polymer can have a modulus of elasticity ranging between 1 GPa to 20 GPa. In some implementations, the electrically conductive polymer can have a modulus of elasticity ranging between 0.1 GPa to 100 GPa, between 0.5 GPa to 75 GPa, between 0.75 GPa to 50 GPa, between 0.9 GPa to 40 GPa, or between 0.95 GPa to 25 GPa.

In some implementations, as shown in FIG. 2A, the conductive probe 208 can include an embedded inductive element 240 (also mentioned herein as an “inductive circuit) for testing the test pad 252 of the semiconductor element 250. In some implementations, the embedded inductive element 240 can be in proximity to the tip 210. The inductive element 240 can be in close proximity to the test pad 252 and/or a trace which can sense the magnitude of current flow along a trace and/ or between two test pads 252. With a suitable calibration, as described below, the deformable conductive probe 208 having an inductive element 240 can be applied to test a device (e.g., semiconductor element 250) without scratching the test pads 252 of the device. The inductive element 240 can be embedded within the conductive probe 208 and be comprised of a conductive coil that generates and/or detects electromagnetic fields when an alternating current is applied. For example, the embedded inductive element 240 can allow the conductive probe 208 to measure specific electrical characteristics, such as impedance, inductance, and/or signal integrity, of the test pad 252. The embedded nature of the inductive element 240 can ensure that the conductive probe 208 can perform contactless and/or minimally invasive measurements, minimizing the risk of damage to the test pad 252 while maintaining high precision. Additionally, the embedded inductive element 240 can utilize electromagnetic induction, where a changing current generates a magnetic field, to measure the current flowing through the test pad 252 of the semiconductor element 250. The changing current through the inductive element 240 can generate a magnetic field, which induces a voltage that can be measured. This induced voltage is proportional to the rate of change of the current. The electromagnetic induction can also detect alternating current (AC) measurements, as the changing current induces a voltage in the embedded inductive element 240, which can be translated into a current reading. The inductive element 240 in the conductive probe 208 can determine if the connection between itself and the test pad 252 is open by utilizing its inductive properties. When the loop is closed, the inductive element 240 can measure changes in magnetic fields or current flow, providing accurate readings of electrical characteristics. However, if the connection is open, the lack of continuity will result in a failure to detect the expected inductance or current flow, indicating an interruption.

The inductive element 240 can be also calibrated to ensure accuracy and reliable performance under test conditions. Calibration can involve compensating for factors that can affect the inductance of the inductive element 240, such as parasitic capacitance, resistance, temperature variations, and/or surrounding electromagnetic interference. One calibration method is impedance measurement calibration, where the inductive element 240 is tested against a reference circuit with known inductance values. By comparing the readings from the inductive element 240 of the conductive probe 208 to these known values, adjustments can be made to match the expected inductances. Calibration can also include temperature compensation since the inductance of the inductive element 240 can vary with temperature. By measuring the inductive element 240 at different temperatures, a calibration curve can be developed and/or real-time correction algorithms can be applied to ensure accuracy across a range of temperatures. Another instance of calibration can be adjusting the frequency response of the inductive element 240. The inductance can behave differently across various frequencies, and by using a signal generator to input different frequencies, the response of the inductive element 240 can be compared to expected values. This can help ensure accurate measurements, particularly in high-frequency applications. Parasitic effects, such as capacitance and resistance, can also influence the performance of the inductive element 240, so calibration often includes compensating for these by using specialized equipment like an LCR meter to account for and subtract their impact. Also, zeroing and offset adjustments (e.g., resetting the conductive probe 208 to a known baseline state), such as no current or electromagnetic field, can eliminate any offsets caused by the internal components of the conductive probe 208 and/or environmental factors. This ensures that any subsequent readings are accurate and start from a true zero point. The conductive probe 208 can be formed on (e.g., integrated with) and/or to the metallic conductors 206 using several different process. For example, the conductive probe 208 can be formed on the metallic conductors 206 through additive manufacturing (e.g., 3D printing). Additive manufacturing for forming the conductive probe 208 can involve using additive manufacturing techniques to create precise, complex structures layer by layer from conductive materials. This process can utilize conductive inks and/or filaments comprised of metal nanoparticles and/or polymers infused with conductive particles. Directly printing the conductive probe 208 can allow for customization, improving performance and integration with electronic components. In other examples, the conductive probe 208 can be formed using molding methods. Molding methods for integrating and/or forming the metallic conductors 206 can include creating a mold into which conductive materials are cast, injected, and/or pressed to achieve the desired shape. Some molding techniques can include injection molding, compression molding, and/or transfer molding. Injection Molding comprise injecting molten conductive materials into a mold cavity, which can be ideal for high-volume, precise shapes. Compression Molding involves placing conductive materials into a heated mold and pressed into shape, suitable for larger parts and composites. In transfer molding, preheated material can be forced into a mold cavity, combining injection and compression techniques for intricate shapes. The conductive probe 208 can also be formed on (e.g., integrated with) the metallic conductors 206 using vacuum molding. Vacuum forming is a version of thermoforming, where a conductive material is heated until pliable, then draped over a mold. A vacuum is applied, pulling the conductive material tightly against the mold to create a detailed and precise shape.

As illustrated in FIG. 2A, the semiconductor element 250 can include a test pad 252 in which the testing probe 200 contacts for testing the semiconductor element 250. In some implementations, the test pad 252 can include a hard coating to further prevent indentation. For example, the test pad 252 can include a coating 254. The coating 254 can be comprised of ITO, Rhodium, Iridium, and/or any other suitable hard conductor. As the testing probe 200 presses against the test pad 252, the testing probe 200 can deform to minimize and/or eliminate damage to the test pad 252 and/or surfaces of the semiconductor element 250. By deforming, the testing probe 200 can leave no defects, damages, etc. on the test pad 252 from testing. Additionally, since the test pad 252 is not damaged during testing, there is no need for additional processing (e.g., CMP). During operation of the testing probe 200, a can be applied to the conductive probe 208 which causes the conductive probe 208 to deform and/or conform to a surface geometry of the test pad 252 without leaving permanent indentations. Applying the force to the conductive probe 208 can ensure complete contact without damaging the surface geometry of the test pad 252. Additionally, the test pad 252 can comprise input and output pads for testing the physical functionality, electrical connectivity and functionality, and/or optical functionality of the semiconductor element 250. Input/output pads (I/O pads) can be utilized as interface points for electrical signals, power, and ground connections. Additionally, I/O pads facilitate signal transmission, power supply, grounding, and/or data communication in the semiconductor element 250. As explained above, the test pad 252 can provide contact points for electrical signals. During wafer-level testing, contact test pad 252 allow for test equipment to transmit and/or apply input signals (e.g., test signals) to activate the semiconductor element 250 and measure output responses of the semiconductor element 250. This process verifies the physical functionality of the semiconductor element 250, checks electrical characteristics (e.g., electrical connectivity and functionality), optical characteristics (e.g., optical functionality), and/or ensures reliability through stress testing like burn-in. Additionally, an electrical response from the semiconductor element 250 in response to a test signal can be measured. The electrical response can include at least one of voltage, current, and/or resistance. Wafer-level testing can also include comparing a measured electrical response to a predetermined standard response for a properly functioning semiconductor element. Automated test equipment can use I/O pads to conduct extensive, automated testing, ensuring performs correctly before integration into electronic devices by identifying known good dies (KGDs) prior to simulation of a wafer. In some implementations, the semiconductor element 250 can comprise microelectronic elements, such as semiconductor elements, including, for example, integrated device dies, wafers, passive devices, discrete active devices such as power switches, MEMS, etc.

In testing the semiconductor element 250 with the testing probe 200, the base test structure 202 having the conductive probe 208 can be provided over the test pad 252 of the elastically deformable testing probe 200. The conductive probe 208 can contact the test pad 252 (e.g., a plurality of test pads 252) of the testing probe 200. In some implementations, contacting the test pad 252 with the conductive probe 208 leaves no indentation (e.g., a mark and/or a defect) a surface of the test pad 252 during. Additionally, the conductive probe 208 can elastically deform to minimize and/or eliminate probe marks on the semiconductor element 250. For example, the protective spherical tip shown in FIG. 2C can prevent indentation defects from occurring on the test pad 252. A force can be applied to the conductive probe 208 such that the conductive probe 208 deforms and/or conforms to a surface geometry of the test pad 252 without leaving permanent indentations. The force can ensure complete contact between the conductive probe 208 and the test pad 252. In some implementations, in contacting the test pad 252, the conductive probe 208 leaves an indentation on a surface of the plurality of test pads of a depth less than 300 nm. In some implementations, the conductive probe 208 leaves an indentation on a surface of the plurality of test pads of a depth less than 100 nm. In some implementations, the conductive probe 208 leaves an indentation on a surface of the plurality of test pads of a depth between 10 nm to 500 nm, between 15 nm to 300 nm, between 20 nm to 250 nm, between 25 nm to 200 nm, between 50 nm to 150 nm, or between 75 nm to 125 nm.

Contacting the test pad 252 with the conductive probe 208 can establish an electrical contact between the test pad 252 and the conductive probe 208. The testing probe 200 can test the semiconductor element 250 by transmitting test signals into the elastically deformable testing probe 200 through the conductive probe 208. These signals are designed to activate various circuits within the semiconductor element 250, simulating operational conditions. The responses of the semiconductor element 250 to the test signals are captured and recorded by circuitry included in the testing probe 200. This data includes voltage levels, current flows, and timing information, which are important for assessing the performance of the semiconductor elements. The acquired data is then analyzed to determine the functionality and performance of the elastically deformable testing probe 200. This analysis identifies defects such as open circuits, short circuits, and/or parameter deviations from specifications. After testing is completed, the conductive probe 208 can disconnect form the test pad 252.

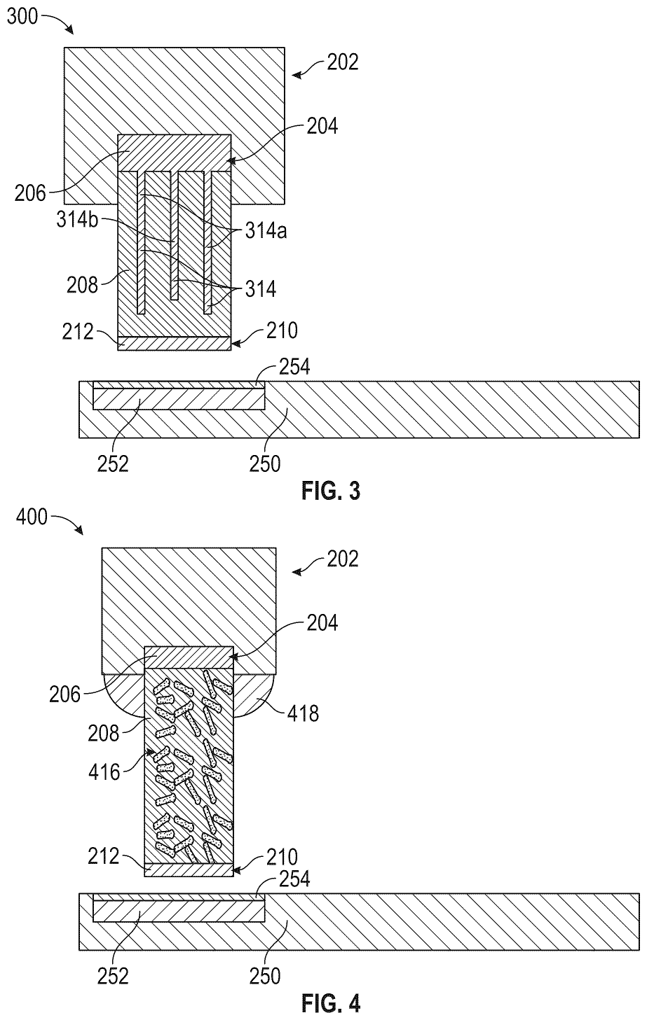

FIG. 3 illustrates a schematic side sectional view of another exemplary elastically deformable testing probe 300 and the semiconductor element 250. Unless otherwise noted, the components of FIG. 3 can be the same as or generally similar to like-numbered components of FIGS. 2A-2C. For example, the testing probe 300 can include a base test structure 202, an electrically conductive layer 204, metallic conductors 206, a conductive probe 208, a tip 210, and a protective tip layer 212.

As shown in FIG. 3, the testing probe 300 can include one or more conductive filaments 314 embedded within the conductive probe 208 to improve conductivity. The conductive filaments 314 embedded within the conductive probe 208 can serve as a pathway for electrical signals from the tip 210 to the base test structure 202. The conductive filaments 314 can enable conductive probe 208 to transmit electrical currents accurately. The conductive filaments 314 can be made from materials with high electrical conductivity, such as copper, silver, graphite, and/or carbon-based composites, and can be designed to maintain low resistance. The conductive filaments 314 can include a first set of conductive filaments 314a having a length less than 30% of the conductive probe 208 and a second set of conductive filaments 314b having a length less than 20% of the conductive probe 208. In some implementations, the first set of conductive filaments 314a has a length between 20% to 40% of the length of the conductive probe 208, between 22.5% to 37.5% of the length of the conductive probe 208, between 25% to 35% of the length of the conductive probe 208, or between 27.5% to 32.5% of the length of the conductive probe 208. In some implementations, the second set of conductive filaments 314b has a length between 10% to 30% of the length of the conductive probe 208, between 12.5% to 27.5% of the length of the conductive probe 208, between 15% to 25% of the length of the conductive probe 208, or between 17.5% to 22.5% of the length of the conductive probe 208. In some implementations, the conductive filaments 314 can be formed in different geometrical patterns within the conductive probe 208. The geometrical patterns can be comprised of linear and/or non-linear arrays or circular arrays of conductive filaments. Regardless of the geometric pattern of the conductive filaments 314, in some instances the volume or area fraction of the conductive filaments can be less than 60% of the conductive probe 208, and, in other instances, less than 50%, and less than 35%.

FIG. 4 illustrates a schematic side sectional view of another exemplary elastically deformable testing probe 400 and the semiconductor element 250. Unless otherwise noted, the components of FIG. 4 can be the same as or generally similar to like-numbered components of FIGS. 2A-3. For example, the testing probe 400 can include a base test structure 202, an electrically conductive layer 204, metallic conductors 206, a conductive probe 208, a tip 210, and a protective tip layer 212.

As shown in FIG. 4, the testing probe 400 can include reinforcing material 416 for improving electrical conductivity and the elastic property of the conductive probe 208. The reinforcing material 416 can be comprised of various conductive materials. For example, the reinforcing material 416 can be comprised of copper, silver, graphite, carbon nanotubes (CNT), etc. In some implementations, the reinforcing material 416 content of the reinforcing material 416 is less than 60% of the conductive probe 208. In some implementations, the reinforcing material 416 content of the reinforcing material 416 is between 20% to 50%, between 22.5% to 47.5%, between 25% to 45%, between 27.5% to 42.5%, between 30% to 40%, or between 32.5% to 37.5% of the conductive probe 208. In some implementations, the graphite content of the reinforcing material 416 is less than 15% of the conductive probe 208. In some implementations, the silver content of the reinforcing material 416 is between 1% to 30%, between 2.5% to 27.5%, between 5% to 25%, between 7.5% to 22.5%, between 10% to 20%, or between 12.5% to 17.5% of the conductive probe 208. In some implementations, the CNT content of the reinforcing material 416 is less than 5% of the conductive probe 208. In some implementations, the silver content of the reinforcing material 416 is between 1% to 10%, between 2% to 8%, between 2.5% to 7.5%, between 3% to 7%, between 3.5% to 6.5%, between 4% to 6%, between 4.25% to 5.75%, between 4.5% to 5.5%, or between 4.75% to 5.25% of the conductive probe 208.

The testing probe 400 can also include an underfill layer 418 which can be formed around a base of the conductive probe 208. The underfill layer 418 can be comprised of organic materials like epoxy resins, silicone elastomers, polyurethane, and/or thermoplastic polymers, or inorganic materials like glass-filled compounds and silica fillers, which offer protection against environmental factors while also enhancing mechanical strength.

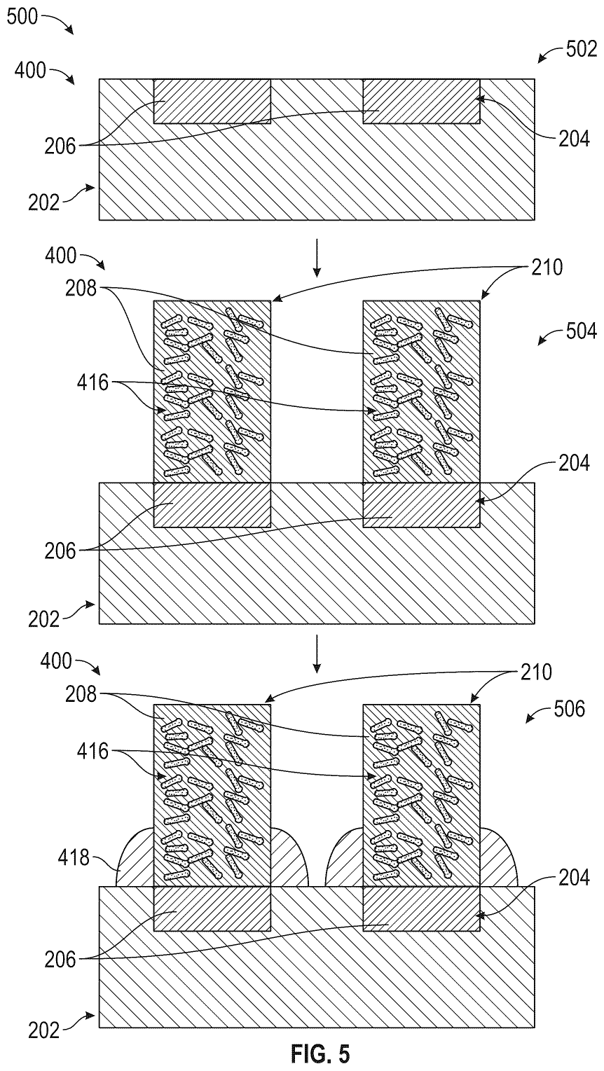

FIG. 5 is a graphical flow diagram illustrating an example process 500 for fabricating the testing probe 400 reinforced with conductive particles (e.g., reinforcing material 416). At step 502, the base test structure 202 can be formed. The base test structure 202 can be formed with the electrically conductive layer 204. The electrically conductive layer 204 can be comprised of metallic conductors 206. The metallic conductors 206 can be at least partially embedded in the base test structure 202.

At step 504, the conductive probe 208 comprised of the electrically conductive polymer can be formed on (e.g. integrated with) the metallic conductors 206 of the electrically conductive layer 204. Forming conductive probe 208 can include the electrically conductive polymer comprised of a coating of an elastically deformable conductive polymer, which, in some implementations, can also include the reinforcing material 416. As mentioned above, the conductive probe 208 can be integrated and/or formed through additive manufacturing (e.g., 3D printing), a molding process, and/or a vacuum forming process. Additionally, a protective coating (e.g., protective tip layer 212 can be deposed on the tip 210 of the conductive probe 208. The tip 210 can be on an opposite surface from the base test structure 202. At step 506, the underfill layer 418 can be formed around a base of the conductive probe 208.

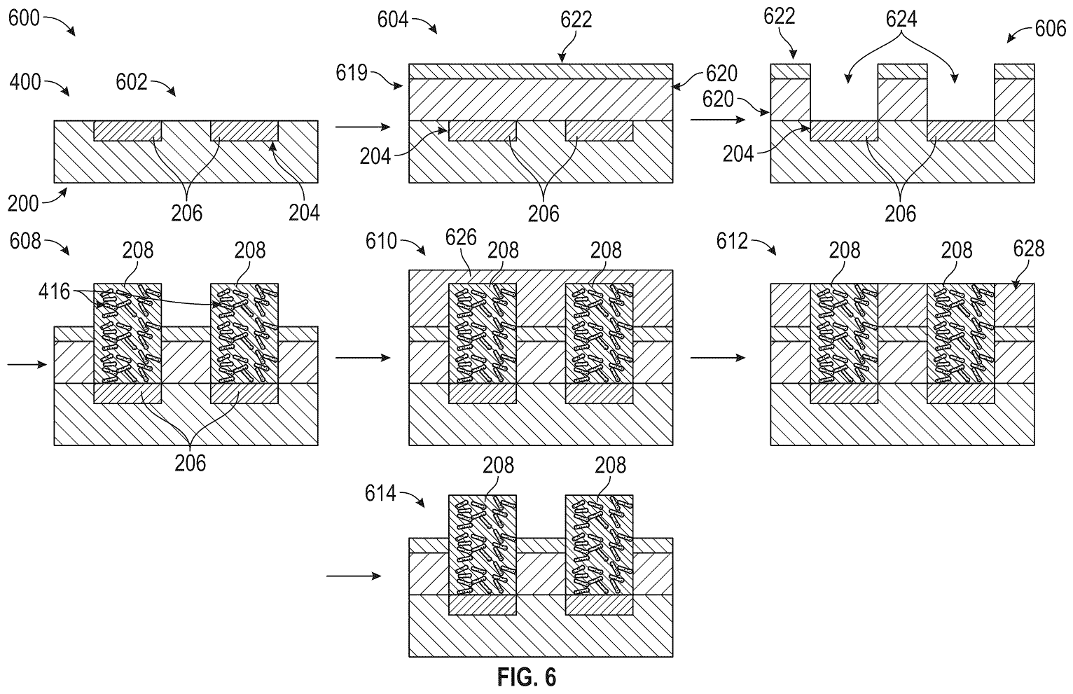

FIG. 6 is a graphical flow diagram illustrating another example process 600 for fabricating the testing probe 400 reinforced with conductive particles (e.g., reinforcing material 416). At step 602, the base test structure 202 can be formed. The base test structure 202 can be formed with the electrically conductive layer 204. The electrically conductive layer 204 can be comprised of metallic conductors 206. The metallic conductors 206 can be at least partially embedded in the base test structure 202.

At step 604, one or more dielectric layers 619 can be formed over the electrically conductive layer 204. For example, an organic dielectric layer 620 can be formed over the electrically conductive layer 204. Additionally, an inorganic dielectric layer 622 can be formed over the organic dielectric layer 620. In some implementations, the organic dielectric layer 620 is thicker than the inorganic dielectric layer 622.

At step 606, the dielectric layers 619 (e.g., the organic dielectric layer 620 and the inorganic dielectric layer 622) can be patterned to create openings 624 and expose the metallic conductors 206 of the electrically conductive layer 204. For example, photolithography, laser ablation, chemical etching, mechanical scraping or etching, and/or dry or wet etching can be used to pattern the dielectric layers 619 and expose the electrically conductive layer 204. Photolithography involves coating the dielectric layers 619 with a photoresist, exposing the photoresist to UV light through a mask, and developing the resist to create a pattern before etching away the unexposed areas. Laser ablation uses a laser to remove parts of the dielectric layers 619, allowing for high-resolution patterning. Chemical etching involves applying a chemical etchant to dissolve selected areas of the dielectric layers 619 based at least on a pre-applied mask and/or pattern. Mechanical scraping or etching uses physical tools and/or abrasives to manually or automatically remove the dielectric layers 619. Lastly, dry or wet etching employs plasma and/or liquid chemicals to selectively etch the dielectric layers 619, with dry etching offering precision and wet etching for larger areas.

At step 608, the conductive probe(s) 208 comprised of the electrically conductive polymer can be formed within the openings 624 on the metallic conductors 206 of the electrically conductive layer 204. Forming conductive probe 208 can include the electrically conductive polymer comprised of a coating of an elastically deformable conductive polymer, which, in some implementations, can also include the reinforcing material 416. As mentioned above, the conductive probe 208 can be formed on (e.g., integrated with) the metallic conductors 206 through additive manufacturing (e.g., 3D printing), a molding process, and/or a vacuum forming process. Additionally, a protective coating (e.g., protective tip layer 212 can be deposed on the tip 210 of the conductive probe 208. The tip 210 can be on an opposite surface from the base test structure 202.

At step 610, a protective layer 626 (e.g., a passivation layer) can be coated over the conductive probe(s) 208. The protective layer 626 can be comprised of materials such as silicon nitride (Si₃N₄), silicon dioxide (SiO₂), and polyimide. These materials can provide insulation, chemical resistance, and/or durability during assembly.

At step 612, a portion of the conductive probe(s) 208 and the protective layer 626 can be planarized to create a planarized surface 628. By planarizing the conductive probe 208 and protective layer 626, a smooth, flat surface can be created. The smooth, flat surface can assist with the subsequent manufacturing steps, such as photolithography and/or the deposition of additional layers. Chemical Mechanical Planarization (CMP) can be used for planarizing, which uses both chemical and mechanical processes to remove material and level the surface. This can ensure uniformity across the planarized surface 628.

At step 614, the protective layer 626 can be selectively removed from the planarized surface 628 to form the protruding conductive probe(s) 208. The conductive probe(s) 208 can extend beyond the dielectric layers 619 (e.g., the organic dielectric layer 620 and/or the inorganic dielectric layer 622). The dielectric layers 619 can provide protection against environmental factors while also enhancing mechanical strength.

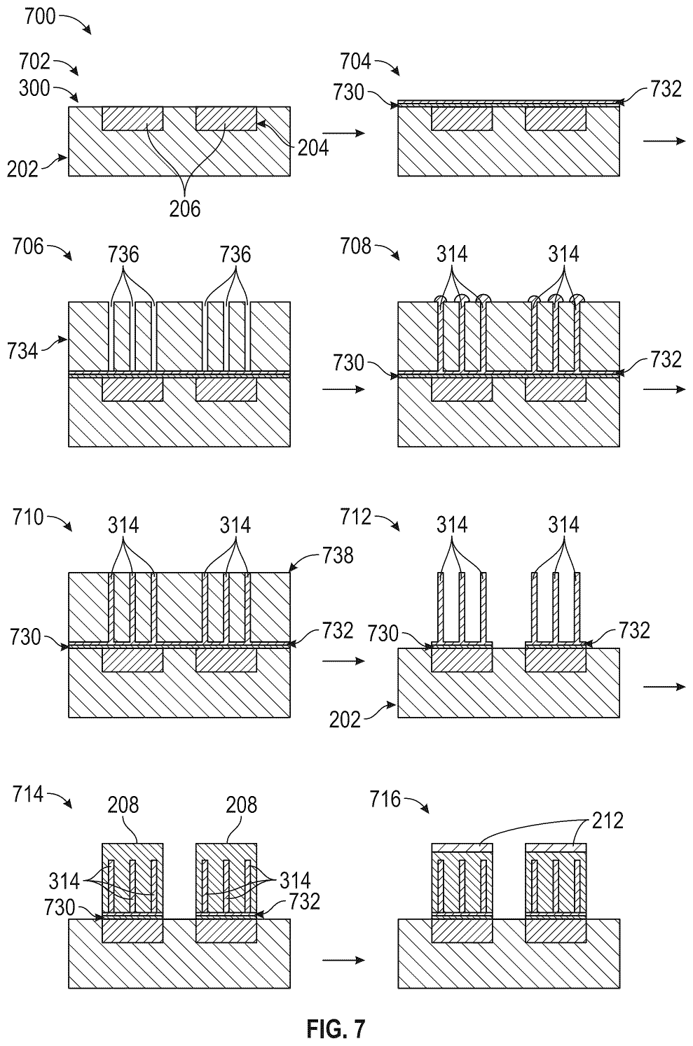

FIG. 7 is a graphical flow diagram illustrating another example process 700 for fabricating the testing probe 300 having one or more conductive filaments 314 embedded within the conductive probe 208. At step 702, the base test structure 202 can be formed. The base test structure 202 can be formed with the electrically conductive layer 204. The electrically conductive layer 204 can be comprised of metallic conductors 206. The metallic conductors 206 can be at least partially embedded in the base test structure 202.

At step 704, an adhesion layer 730 can be formed over the electrically conductive layer 204. Additionally, a seed layer 732 can be formed over the adhesion layer 730. The adhesion layer 730 can promote strong bonding between two materials (e.g., the base test structure 202 and the seed layer 732) that may not naturally adhere well to each other. In some implementations, the adhesion layer 730 can be comprised of a thin metal layer (such as titanium, chromium, and/or tantalum) formed (e.g., deposited) on the electrically conductive layer 204 of the base test structure 202 before adding other layers, like a conductive or dielectric material. The adhesion layer 730 can ensure that subsequent layers (e.g., seed layer 732) remain attached to the base test structure 202, preventing delamination and/or peeling. The adhesion layer 730 can provide the bond between the base test structure 202 and the seed layer 732, while the seed layer 732 serves as a base for further material deposition. The seed layer 732 can serve as a foundation for the growth of another material, for example, in processes like electroplating and/or electroless plating. The seed layer 732 can provide a conductive surface on which additional metal layers (such as copper, nickel, or gold) can be formed (e.g., deposited) uniformly. The seed layer 732 can also ensure that the formed material grows evenly and adheres well to the adhesion layer 730, leading to consistent thickness and electrical properties across the layer. The seed layer can be thin and can be enhanced by the adhesion layer 730 to improve bonding.

At step 706, a resist layer 734 is coated over the adhesion layer 730 and/or seed layer 732. The resist layer 734 can be a light-sensitive material used in photolithography and other patterning processes to define specific areas on the adhesion layer 730 and/or seed layer 732 for further processing, such as etching, doping, and/or metal deposition. The resist layer 734 can be either a positive resist, where the exposed areas become soluble and are removed during development, or a negative resist, where the exposed areas harden and the unexposed regions are removed. The resist layer 734 can be patterned for cavities 736 (e.g., filamentary and/or thin plate cavities). For example, the cavities 736 can be created in the resist layer 734 through processes like photolithography, can later be filled with a conductive material during the plating process.

At step 708, conductive layers (e.g., conductive filaments 314) can be formed in the patterned cavities of step 704. The conductive filaments 314 can be formed by thru-mask plating methods. The 314 can be formed using an electroplating process, where the resist layer 734 is submerged in an electrolytic solution, and an electric current is applied. The metal ions in the solution are reduced and formed (e.g., deposited) onto the exposed conductive areas within the cavities (e.g., seed layer 732). The metal gradually fills the cavities, and the plating continues until the desired thickness is achieved (e.g., filling the cavities completely and/or partially). The 314 can also be formed using an electroless plating by using a chemical reaction to deposit metal onto the exposed areas of the seed layer 732. Electroless plating can be used for uniformly filling cavities without the need for a continuous conductive path throughout the resist layer 734. In some implementations, the cavity 736 can be filled with conductive material by screen printing and/or 3D printing methods.

At step 710, a portion of the resist layer 734 and of the conductive filaments 314 can be planarized to create a planarized surface 738. By planarizing the resist layer 734 and of the conductive filaments 314, a smooth, flat surface can be created. The smooth, flat surface can assist with the subsequent manufacturing steps, such as photolithography and/or the deposition of additional layers. Chemical Mechanical Planarization (CMP) can be used for planarizing, which uses both chemical and mechanical processes to remove material and level the surface. This can ensure uniformity across the planarized surface 738. In some implementations, mechanical milling methods can be used for the planarized surface 738.

At step 712, a first portion of the adhesion layer 730, the seed layer 732, and/or the planarized surface 738 can be selectively removed from the base test structure 202 to expose the conductive filaments 314. A second portion of the adhesion layer 730 and/or the seed layer 732 can remain underneath the conductive filaments 314. The base test structure 202 can be cleaned to remove contaminants like dust, oils, oxides, and/or residues to prepare the base test structure 202 for subsequent manufacturing steps. For example, the base test structure 202 can be cleaned in several different ways such as with a solvent such as acetone or isopropyl alcohol, using ultrasonic cleaning using sound waves in a liquid medium, acid or base cleaning to remove inorganic residues, and/or plasma cleaning for organic contaminants.

At step 714, the conductive probe(s) 208 comprised of the electrically conductive polymer can be selectively formed (e.g., integrated) over the conductive filaments 314 and on the metallic conductors 206 of the electrically conductive layer 204. As mentioned above, the conductive probe 208 can be integrated and/or formed through additive manufacturing (e.g., 3D printing), a molding process, and/or a vacuum forming process. In some implementations, the exposed tip (e.g., 210) of the coated conductive probe 208 can be planarized at low pressure to form a smooth top surface before subsequent process step.

Additionally, a protective coating (e.g., protective tip layer 212 can be deposed on the tip 210 of the conductive probe 208. The tip 210 can be on an opposite surface from the base test structure 202

At step 716, a conductive and/or protective tip layer 212 can be disposed over a tip 210 of the conductive probe 208 for further preventing indentation defects to a test pad (e.g., test pad 252). The protective tip layer 212 can have a hardness greater than that of the conductive probe 208. The tip layer 212 can be comprised of various materials such as Indium Tin Oxide (ITO), Rhodium, Iridium, etc.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564 , filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

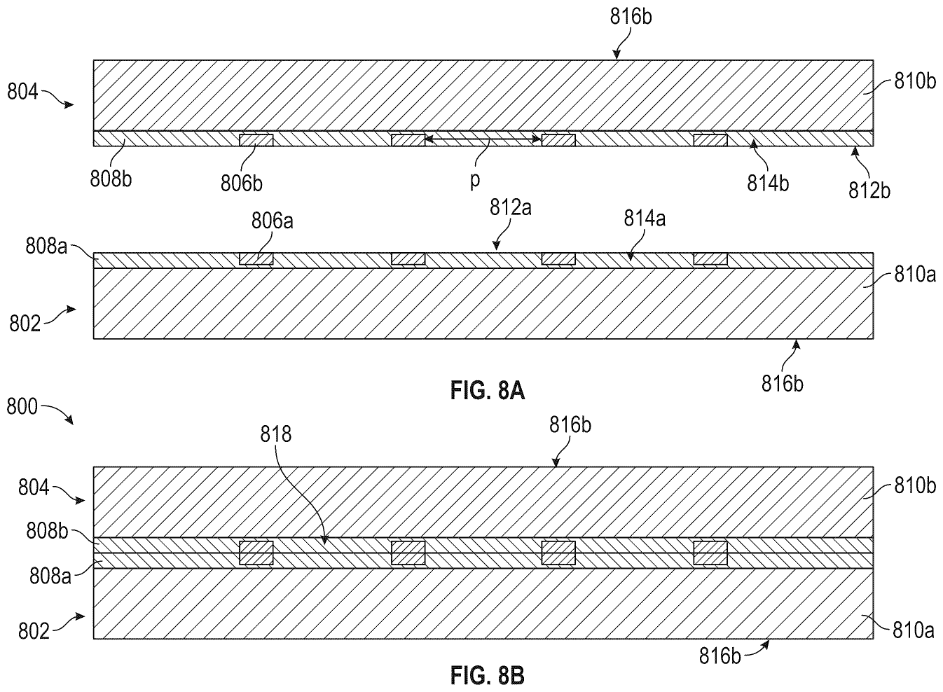

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 8B, a bonded structure 800 comprises the first and second elements 802 and 804 that are directly bonded to one another at a bond interface 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO3) or lithium niobate (LiNbO3), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 8A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 111 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

In the foregoing specification, the systems and processes have been described with reference to specific implementations thereof. It will, however, be evident that various modifications and changes may be made thereto without departing from the broader spirit and scope of the implementations disclosed herein. The specification and drawings are, accordingly, to be regarded in an illustrative rather than restrictive sense.

Indeed, although the systems and processes have been disclosed in the context of certain implementations and examples, it will be understood by those skilled in the art that the various implementations of the systems and processes extend beyond the specifically disclosed implementations to other alternative implementations and/or uses of the systems and processes and obvious modifications and equivalents thereof. In addition, while several variations of the implementations of the systems and processes have been shown and described in detail, other modifications, which are within the scope of this disclosure, will be readily apparent to those of skill in the art based upon this disclosure. It is also contemplated that various combinations or sub-combinations of the specific features and implementations of the implementations may be made and still fall within the scope of the disclosure. It should be understood that various features and implementations of the disclosed implementations can be combined with, or substituted for, one another in order to form varying modes of the implementations of the disclosed systems and processes. Any methods disclosed herein need not be performed in the order recited. Thus, it is intended that the scope of the systems and processes herein disclosed should not be limited by the particular implementations described above.

It will be appreciated that the systems and methods of the disclosure each have several innovative implementations, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate implementations also may be implemented in combination in a single implementations. Conversely, various features that are described in the context of a single implementation also may be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every implementation.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain implementations include, while other implementations do not include, certain features, elements and/or states. Thus, such conditional language is not generally intended to imply that features, elements and/or states are in any way required for one or more implementations.

While certain implementations have been described, these implementations have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative implementations may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various implementations described above can be combined to provide further implementations. The accompanying claims and their equivalents are intended to cover such forms or modifications as would fall within the scope and spirit of the disclosure.

Several illustrative examples of testing probes and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain implementations require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the implementations shown herein but are to be accorded a fair interpretation consistent with this disclosure, the principles and the novel features disclosed herein.

1. -101. (canceled)

102. A deformable electrical testing probe, the testing probe comprising:
a base test structure having an electrically conductive layer comprising one or more metallic conductors; and
a conductive probe comprising an electrically conductive polymer on the one or more metallic conductors of the electrically conductive layer.

103. The testing probe of claim 102, wherein the conductive probe is formed through at least one of additive manufacturing, a molding process, and vacuum forming.

104. The testing probe of claim 102, wherein the conductive probes comprises a tip opposite from the electrically conductive layer, wherein the tip comprises a conductive tip layer having a hardness greater than that of the conductive probes, and wherein the tip comprises a spherical tip or a triangular tip.

105. The testing probe of claim 102, further comprising one or more conductive filaments embedded within the conductive probes, wherein a first set of the one or more conductive filaments comprises a length less than 30% of the conductive probes and a second set of the one or more conductive filaments comprises a length less than 20% of the conductive probes.

106. The testing probe of claim 102, further comprising a reinforcing material embedded within the conductive probes, wherein the reinforcing material within the conductive probe comprises at least one of a composite material and a metallic element.

107. The testing probe of claim 102, wherein an elastic modulus of the electrically conductive polymer is between 1 GPa to 20 GPa.

108. The testing probe of claim 102, wherein the conductive probe is elastically deformable and minimizes or eliminates probe marks on a tested device.

109. The testing probe of claim 102, wherein the conductive probe comprises a plurality of conductive probes.

110. The testing probe of claim 102, wherein the conductive probe is integrated with the one or more metallic conductors of the electrically conductive layer.

111. A deformable electrical testing probe, the testing probe comprising:
a base test structure having an electrically conductive layer comprising one or more metallic conductors;
one or more dielectric layers formed over the electrically conductive layer; and
a conductive probe comprising an electrically conductive polymer on the one or more metallic conductors of the electrically conductive layer and protruding through the one or more dielectric layers.

112. The testing probe of claim 111, wherein the conductive probes comprises a tip opposite from the electrically conductive layer, wherein the tip comprises a conductive tip layer having a hardness greater than that of the conductive probes, and wherein the tip comprises a spherical tip or a triangular tip.

113. The testing probe of claim 111, further comprising one or more conductive filaments embedded within the conductive probe, wherein a first set of the one or more conductive filaments comprises a length less than 30% of the conductive probes and a second set of the one or more conductive filaments comprises a length less than 20% of the conductive probes.

114. The testing probe of claim 111, further comprising a reinforcing material embedded within the conductive probes, wherein the reinforcing material within the conductive probe comprises at least one of a composite material and a metallic element.

115. The testing probe of claim 111, wherein the one or more dielectric layers comprise an organic dielectric layer formed on the electrically conductive layer and an inorganic dielectric layer formed over the organic dielectric layer, and wherein the organic dielectric layer is thicker than the inorganic dielectric layer.

116. A deformable electrical testing probe having conductive filaments, the testing probe comprising:
a base test structure comprising an electrically conductive layer having one or more metallic conductors;
an adhesion layer formed on the electrically conductive layer and a seed layer formed on the adhesion layer; and
a conductive probe comprising an electrically conductive polymer on the seed layer over the one or more metallic conductors of the electrically conductive layer.

117. The testing probe of claims 116, wherein the conductive probes comprises a tip opposite from the electrically conductive layer, and wherein the tip comprises a conductive tip layer having a hardness greater than that of the conductive probes, and wherein the tip comprises a spherical tip or a triangular tip.

118. The testing probe of claims 116, further comprising one or more conductive filaments embedded within the conductive probes, wherein the one or more conductive filaments comprises a first set of conductive filaments and a second set of conductive filaments, and wherein the first set of the one or more conductive filaments comprises a length less than 30% of the conductive probes and the second set of the one or more conductive filaments comprises a length less than 20% of the conductive probes.

119. The testing probe of claims 116, further comprising an underfill around a base of the conductive probes.

120. The testing probe of claims 116, wherein the conductive probe is elastically deformable.

121. The testing probe of claims 116, wherein the conductive probe is integrated with the seed layer over the one or more metallic conductors.
